(19) United States
(12) Patent Application Publication
(10) Pub. No.: US 2024/0072007 A1
(43) Pub. Date: Feb. 29, 2024

(54) SEMICONDUCTOR PACKAGE

(71) Applicant: Samsung Electronics Co., Ltd., Suwon-si (KR)

(72) Inventors: In Lee, Suwon-si (KR); Taeyoung Kim, Suwon-si (KR)

(21) Appl. No.: 18/331,973

(22) Filed: Jun. 9, 2023

(30) Foreign Application Priority Data
Aug. 29, 2022 (KR) 10-2022-0108654

(51) Int. Cl. H01L 25/065; H01L 23/00; H01L 23/498

(52) U.S. Cl. CPC H01L 25/0657; H01L 23/49838; H01L 24/16; H01L 2224/16148; H01L 2224/16227; H01L 2225/06513; H01L 2225/06541; H01L 2225/06562; H01L 2924/381

(57) ABSTRACT

A semiconductor package includes a base substrate, a first semiconductor chip mounted on the base substrate, and a second semiconductor chip mounted on the first semiconductor chip. The first semiconductor includes first conductive connection structures that have a first pitch interval in a first direction and a second pitch interval in a second direction, and the second semiconductor chip includes second conductive connection structures that have the first pitch interval in the first direction and the second pitch interval in the second direction. The first conductive connection structures include first power connection structures, first ground connection structures, and first dummy structures. The first ground connection structure or the first dummy structure is between two first power connection structures neighboring in the first direction and between two first power connection structures neighboring in the second direction among the first power connection structures.

### CROSS-REFERENCE TO RELATED APPLICATION

This application is based on and claims priority under 35 U.S.C. § 119 to Korean Patent Application No. 10-2022-0108654, filed on Aug. 29, 2022, in the Korean Intellectual Property Office, the disclosure of which is incorporated by reference herein in its entirety.

### BACKGROUND

The inventive concept relates to a semiconductor package, and more particularly, to a semiconductor package including a plurality of semiconductor chips.

In accordance with the rapid development of the electronics industry and the needs of users, electronic devices are becoming smaller, more multifunctional, and have large capacity. Accordingly, there is a demand for a semiconductor package including a plurality of semiconductor chips. For example, a method of mounting several types of semiconductor chips side-by-side on one package substrate or stacking semiconductor chips and/or packages on one package substrate may be used.

### SUMMARY

The inventive concept provides a semiconductor package including a plurality of semiconductor chips.

According to an aspect of the inventive concept, there is provided a semiconductor package including a base substrate, a first semiconductor chip mounted on the base substrate, and including a first substrate and first conductive connection structures extending into the first substrate, the first conductive connection structures have a first pitch interval in a first direction and a second pitch interval in a second direction perpendicular to the first direction, and a second semiconductor chip mounted on the first semiconductor chip in a third direction perpendicular to the first direction and the second direction, and including a second substrate and second conductive connection structures extending into the second substrate, the second conductive connection structures have the first pitch interval in the first direction and the second pitch interval in the second direction. The first conductive connection structures include first power connection structures, first ground connection structures, and first dummy structures. Any one of the first ground connection structures or any one of the first dummy structures is between two first power connection structures neighboring in the first direction among the first power connection structures. And any one of the first ground connection structures or any one of the first dummy structures is between two first power connection structures neighboring in the second direction among the first power connection structures.

According to another aspect of the inventive concept, there is provided a semiconductor package including a base substrate, a first semiconductor chip mounted on the base substrate, and including a first substrate and first conductive connection structures extending into the first substrate, the first conductive connection structures are arranged in a first direction and a second direction perpendicular to each other, and a second semiconductor chip mounted on the first semiconductor chip in a third direction perpendicular to the first direction and the second direction, and including a second substrate and second conductive connection structures extending into the second substrate, the second conductive connection structures are arranged in the first direction and the second direction. The first conductive connection structures include first power connection structures, first ground connection structures, and first dummy structures. A structure at a first distance in the first direction from each of the first power connection structures is any one of the first ground connection structures or any one of the first dummy structures. A structure at a second distance in the second direction from each of the first power connection structures is any one of the first ground connection structures or any one of the first dummy structures. A structure at the first distance in the first direction from each of the first ground connection structures is any one of the first power connection structures or any one of the first dummy structures. A structure at the second distance in the second direction from each of the first ground connection structures is any one of the first power connection structures or any one of the first dummy structures. The second conductive connection structures include second power connection structures electrically connected to the base substrate through the first power connection structures or the first dummy structures, second ground connection structures electrically connected to the base substrate through the first ground connection structures or the first dummy structures, and second dummy structures.

According to another aspect of the inventive concept, there is provided a semiconductor package including a first substrate, first input/output channel structures extending into the first substrate, and first power/ground connection structures extending into the first substrate, the first power/ground connection structures have a first pitch interval in a first direction and a second pitch interval in a second direction perpendicular to the first direction, and a second semiconductor chip mounted on the first semiconductor chip in a third direction perpendicular to the first direction and the second direction, and including a second substrate, second input/output channel structures extending into the second substrate, and second power/ground connection structures extending into the second substrate, the second power/ground connection structures have the first pitch interval in the first direction and the second pitch interval in the second direction, the first power/ground connection structures include first power connection structures electrically connected to a first power circuit pattern of the first semiconductor chip, second ground connection structures electrically connected to a first ground circuit pattern of the first semiconductor chip, and first dummy structures electrically isolated from the first power circuit pattern and the first ground circuit pattern, the second power/ground connection structures include second power connection structures electrically connected to a second power circuit pattern of the second semiconductor chip, second ground connection structures electrically connected to a second ground circuit pattern of the second semiconductor chip, and second dummy structures electrically isolated from the second power circuit pattern and the second ground circuit pattern. Any one of the first ground connection structures or any one of the first dummy structures is between two first power connection structures neighboring in the first direction among the first power connection structures. Any one of the first ground connection structures or any one of the first dummy structures is between two first power connection structures neighboring in the second direction among the first power connection structures. Any one of the first power connection structures or any one of the first dummy structures is between two first ground connection structures neighboring in the first direction among the first ground connection structures. Any one of the first power connection structures or any one of the first dummy structures is between two first ground connection structures neighboring in the second direction among the first ground connection structures. The second power connection structures are aligned with the first power connection structures or the first dummy structures in the third direction. The second ground connection structures are aligned with the first ground connection structures or the first dummy structures in the third direction. The first input/output channel structures include first input/output connection structures electrically connected to a first input/output circuit pattern and first input/output dummy structures electrically isolated from the first input/output circuit pattern. Andy the second input/output channel structures are aligned with the first input/output dummy structures in the third direction.

### BRIEF DESCRIPTION OF THE DRAWINGS

Embodiments of the inventive concept will be more clearly understood from the following detailed description taken in conjunction with the accompanying drawings in which:

FIG. 1 is a plan view illustrating a semiconductor package according to some embodiments;

FIG. 2 is a plan view illustrating a first semiconductor chip shown in FIG. 1;

FIG. 3 is a cross-sectional view taken along line III-III′ of FIG. 1;

FIG. 4A is an enlarged view illustrating a portion indicated by “IVA” of FIG. 3;

FIG. 4B is an enlarged view illustrating a portion indicated by “IVB” of FIG. 3;

FIG. 4C is an enlarged view illustrating a portion indicated by “IVC” of FIG. 3;

FIG. 5A is an enlarged view illustrating a portion indicated by “VA” of FIG. 3.

FIG. 5B is an enlarged view illustrating a portion indicated by “VB” of FIG. 3.

FIG. 5C is an enlarged view illustrating a portion indicated by “VC” of FIG. 3.

FIGS. 6A to 6C are diagrams illustrating a method of manufacturing a semiconductor package, according to some embodiments;

FIG. 7 is a plan view illustrating a semiconductor package according to some embodiments;

FIG. 8 is a plan view illustrating a first semiconductor chip illustrated in FIG. 7;

FIG. 9 is a cross-sectional view taken along line IX-IX′ of FIG. 7;

FIG. 10 is a perspective view schematically illustrating a layout of first power/ground connection structures of a first semiconductor chip and a layout of second power/ground connection structures of a second semiconductor chip shown in FIG. 7;

FIG. 11 is a plan view illustrating a semiconductor package according to some embodiments;

FIG. 12 is a cross-sectional view taken along line XII-XII′ of FIG. 11.

FIG. 13 is a perspective view schematically illustrating a layout of first power/ground connection structures of a first semiconductor chip and a layout of second power/ground connection structures of a second semiconductor chip shown in FIG. 11;

FIG. 14 is a perspective view schematically illustrating a part of a semiconductor package according to some embodiments, that is, a layout of first power/ground connection structures of a first semiconductor chip and a layout of second power/ground connection structures of a second semiconductor chip; and

FIG. 15 is a perspective view schematically illustrating a part of a semiconductor package according to some embodiments, that is, a layout of first power/ground connection structures of a first semiconductor chip and a layout of second power/ground connection structures of a second semiconductor chip.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

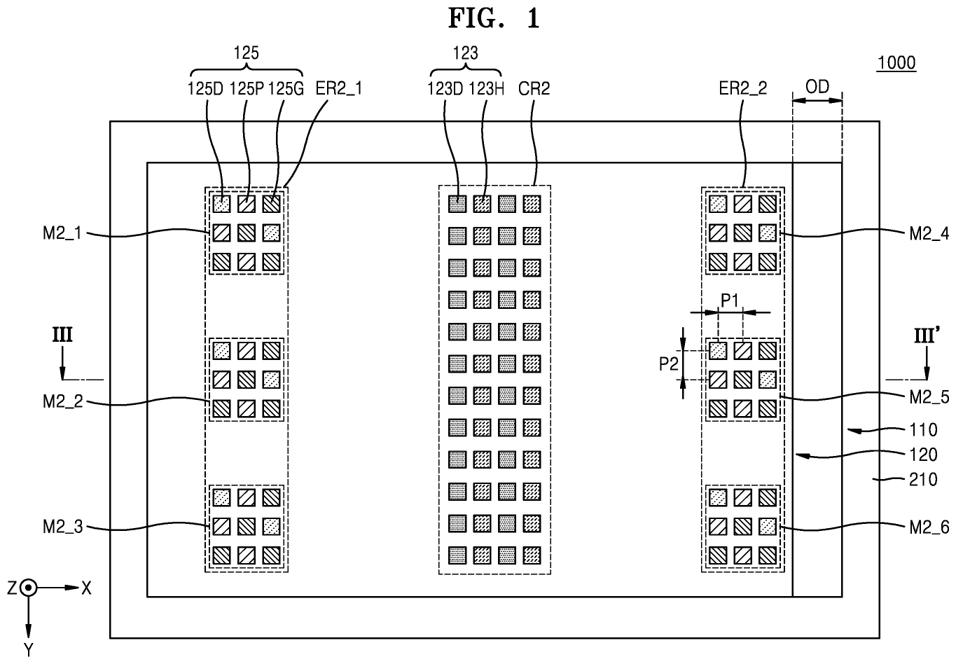

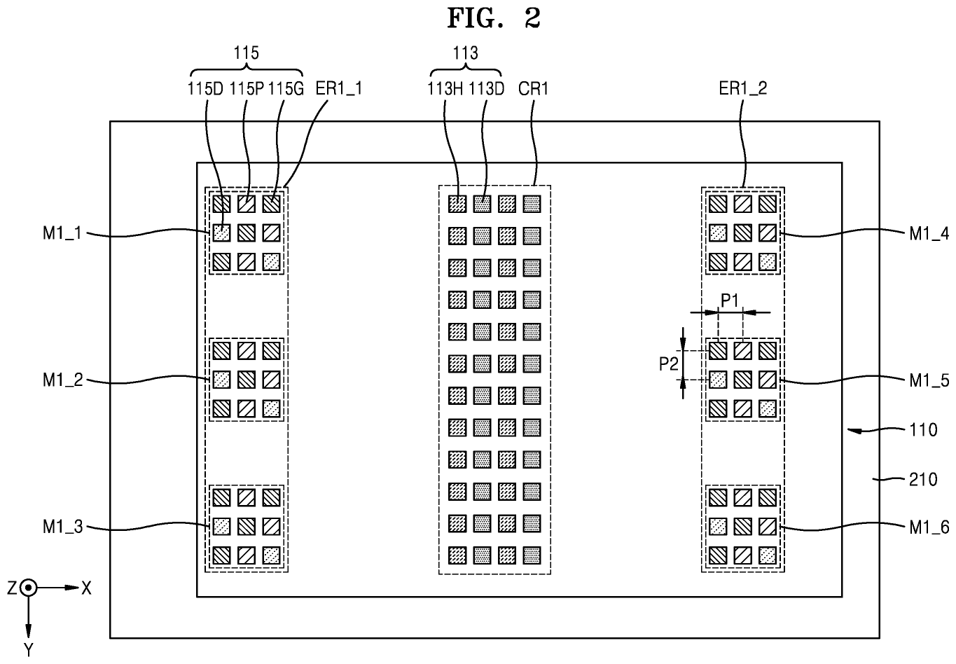

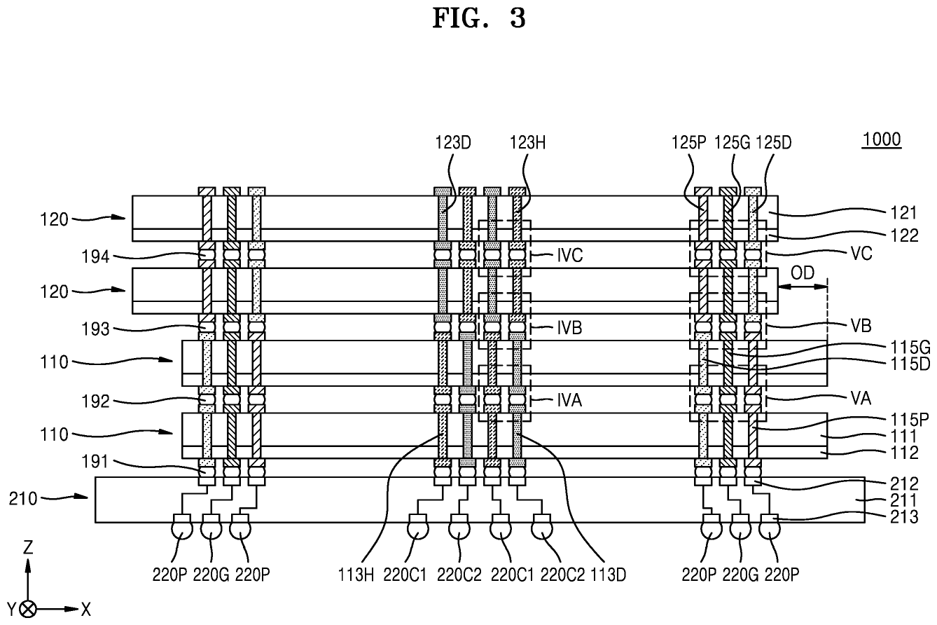

FIG. 1 is a plan view illustrating a semiconductor package 1000 according to some embodiments. FIG. 2 is a plan view illustrating a first semiconductor chip 110 shown in FIG. 1. FIG. 3 is a cross-sectional view taken along line III-III′ of FIG. 1.

Referring to FIGS. 1 to 3, the semiconductor package 1000 may include a base substrate 210 and a plurality of semiconductor chips respectively stacked on the base substrate 210 in a vertical direction (e.g., Z direction) (e.g., at least one first semiconductor chip 110 and at least one second semiconductor chip 120).

The base substrate 210 may generally have a flat plate form or a panel form. The base substrate 210 may include upper and lower surfaces opposite to each other, and each of the upper and lower surfaces thereof may be a plane. Hereinafter, a horizontal direction (e.g., X direction and/or Y direction) may be defined as a direction parallel to the upper surface of the base substrate 210, a vertical direction (e.g., Z direction) may be defined as a direction perpendicular to the upper surface of the base substrate 210, and a horizontal width may be defined as a length in the horizontal direction (e.g., X direction and/or Y direction).

For example, the base substrate 210 may be a printed circuit board (PCB), an interposer, or a semiconductor chip including an integrated circuit. For example, the base substrate 210 may be a PCB, and may include a core insulating layer 211, upper substrate pads 212, and lower substrate pads 213.

The upper substrate pads 212 may be provided on the upper surface of the core insulating layer 211, and the lower substrate pads 213 may be provided on the lower surface of the core insulating layer 211. Internal wiring configured to electrically connect the upper substrate pads 212 to the lower substrate pads 213 may be provided inside the core insulating layer 211. For example, the upper substrate pads 212 and the lower substrate pads 213 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

The base substrate 210 may include external connection terminals respectively attached to the lower substrate pads 213. The external connection terminals may be configured to electrically and physically provide a connection between the base substrate 210 and an external device. The external connection terminals may be formed from, for example, solder balls or solder bumps. The external connection terminals may include a power external connection terminal 220P configured to transmit a power signal, a ground external connection terminal 220G configured to transmit a ground signal, a first channel external connection terminal 220C1 configured to transmit a first input/output channel signal, and a second channel external connection terminal 220C2 configured to transmit a second input/output channel signal. The upper substrate pads 212 of the base substrate 210 may include a power substrate pad electrically connected to the power external connection terminal 220P, a ground substrate pad electrically connected to the ground external connection terminal 220G, a channel first substrate pad electrically connected to the first channel external connection terminal 220C1, and a channel second substrate pad electrically connected to the second channel external connection terminal 220C2.

In some embodiments, the plurality of semiconductor chips included in the semiconductor package 1000 may be semiconductor chips of the same type configured to perform the same function, and may include integrated circuits of the same type. In some embodiments, the plurality of semiconductor chips included in the semiconductor package 1000 may be memory chips. The memory chips may be, for example, volatile memory chips, such as dynamic random access memory (DRAM) or static random access memory (SRAM), or non-volatile semiconductor chips, such as phase-change random access memory (PRAM), magnetoresistive random access memory (MRAM), ferroelectric random access memory (FeRAM), or resistive random access memory (RRAM). In some embodiments, the plurality of semiconductor chips may be high bandwidth memory (HBM) DRAM chips. In some embodiments, the plurality of semiconductor chips included in the semiconductor package 1000 may be logic chips. The logic chips may be, for example, central processing unit (CPU) chips, graphics processing unit (GPU) chips, or application processor (AP) chips.

In some embodiments, the plurality of semiconductor chips included in the semiconductor package 1000 may include different types of semiconductor chips configured to perform different functions, and different types of semiconductor chips may include different types of integrated circuits. For example, at least one of the plurality of semiconductor chips may be a memory chip and at least one other semiconductor chip may be a logic chip.

In some embodiments, the semiconductor package 1000 may include one or more first semiconductor chips 110 mounted on the base substrate 210, and one or more second semiconductor chips 120 mounted on the first semiconductor chip 110. The first semiconductor chip 110 may be defined as a chip configured to transmit/receive a first input/output channel signal to/from the base substrate 210, and the at least one second semiconductor chip 120 may be configured to transmit/receive a second input/output channel signal separate from the first input/output channel signal to/from the base substrate 210. In FIG. 1, the semiconductor package 1000 includes two first semiconductor chips 110 stacked and aligned with one another in the vertical direction (e.g., Z direction), and two second semiconductor chips 120 stacked and aligned with one another in the vertical direction (e.g., Z direction). However, the number of first semiconductor chips 110 and the number of second semiconductor chips 120 are examples, and the number of first semiconductor chips 110 may be one or more, and the number of second semiconductor chips 120 may be one or more in accordance with other embodiments.

The first semiconductor chip 110 may be face-down mounted on the base substrate 210 or the other first semiconductor chip 110. The first semiconductor chip 110 may be mounted on the base substrate 210 through a first connection bump 191, or may be mounted on the other first semiconductor chip 110 through a second connection bump 192. The second semiconductor chip 120 may be face-down mounted on the first semiconductor chip 110 or the other second semiconductor chip 120. The second semiconductor chip 120 may be mounted on the first semiconductor chip 110 through a third connection bump 193, or may be mounted on the other second semiconductor chip 120 through a fourth connection bump 194. For example, the first to fourth connection bumps 191, 192, 193, and 194 may each include a conductive material, for example, solder.

In some embodiments, the two first semiconductor chips 110 may be attached to each other by direct bonding, for example, Cu-to-Cu direct bonding or hybrid direct bonding, and the second connection bump 192 may be omitted. The first semiconductor chip 110 and the second semiconductor chip 120 may be attached to each other by direct bonding, and the third connection bump 193 may be omitted. The two second semiconductor chips 120 may be attached to each other by direct bonding, and the fourth connection bump 194 may be omitted.

The first semiconductor chip 110 and the second semiconductor chip 120 may have the same dimensions. The first semiconductor chip 110 and the second semiconductor chip 120 may have the same horizontal width in a first horizontal direction (e.g., X direction), the same horizontal width in a second horizontal direction (e.g., Y direction), and the same length in a vertical direction (e.g., Z direction).

The two first semiconductor chips 110 may be aligned in the vertical direction (e.g., Z direction), and footprints of the two first semiconductor chips 110 may be identical to each other. Side surfaces of the two first semiconductor chips 110 may be aligned in the vertical direction (e.g., Z direction). The two second semiconductor chips 120 may be aligned in the vertical direction (e.g., Z direction), and footprints of the two second semiconductor chips 120 may be identical to each other. Side surfaces of the two second semiconductor chips 120 may be aligned in the vertical direction (e.g., Z direction).

In some embodiments, the second semiconductor chip 120 may be stacked on the first semiconductor chip 110 in an offset stack or a shift stack. That is, the second semiconductor chip 120 may be laterally offset and stacked on the first semiconductor chip 110, and a part of the second semiconductor chips 120 may protrude laterally from the first semiconductor chip 110. In some embodiments, the second semiconductor chip 120 may be offset in the first horizontal direction (e.g., X direction) and stacked on the first semiconductor chip 110, and a part of the second semiconductor chip 120 may protrude from the first semiconductor chip 110 in the first horizontal direction (e.g., X direction). For example, an offset distance OD between the edge of the second semiconductor chip 120 and the edge of the first semiconductor chip 110 may be between about 100 micrometers (μm) and about 400 μm. In some embodiments, the second semiconductor chip 120 may be offset in the first horizontal direction (e.g., X direction) and the second horizontal direction (e.g., Y direction) and stacked on the first semiconductor chip 110.

The first semiconductor chip 110 may include a first semiconductor substrate 111, conductive first input/output channel structures 113 penetrating or extending into the first semiconductor substrate 111 in the vertical direction (e.g., Z direction), and conductive first power/ground connection structures 115 penetrating or extending into the first semiconductor substrate 111 in the vertical direction (e.g., Z direction). The first input/output channel structures 113 may be configured to transmit a first input/output channel signal (e.g., an input/output data signal, an address signal, and a clock signal) between the first semiconductor chip 110 and an external device. The first power/ground connection structures 115 may be configured to transmit a power signal and a ground signal to the first semiconductor chip 110 provided from the external device.

In some embodiments, the first input/output channel structures 113 may be disposed in a two-dimensional array in a central portion CR1 of the first semiconductor chip 110. That is, the layout of the first input/output channel structures 113 may have two or more rows and two or more columns. Hereinafter, structures arranged in the first horizontal direction (e.g., X direction) are defined to constitute one row of the layout of the structures, and structures arranged in the second horizontal direction (e.g., Y direction) are defined to constitute one column of the layout of the structures. The first input/output channel structures 113 may include first input/output connection structures 113H and first input/output dummy structures 113D. The first input/output connection structures 113H may be electrically connected to the input/output circuit pattern of the first semiconductor chip 110. The first input/output dummy structures 113D may be electrically isolated from the input/output circuit pattern of the first semiconductor chip 110. In some embodiments, the first input/output connection structures 113H may be arranged in the second horizontal direction (e.g., Y direction) to constitute one column, and the first input/output dummy structures 113D may be arranged in the second horizontal direction (e.g., Y direction) to constitute one column. In this regard, the column of the first input/output connection structures 113H and the column of the first input/output dummy structures 113D may be spaced apart from each other in the first horizontal direction (e.g., X direction). In one row of the first input/output channel structures 113, one first input/output connection structure 113H and one first input/output dummy structure 113D may be alternately disposed.

In some embodiments, the first power/ground connection structures 115 may be respectively disposed in a first edge portion ER1_1 on one side (e.g., left side) of the central portion CR1 of the first semiconductor chip 110, and in a second edge portion ER1_2 disposed on the other side (e.g., right side) of the central portion CR1 of the first semiconductor chip 110. The first edge portion ER1_1 and the second edge portion ER1_2 may be spaced apart from each other in the first horizontal direction (e.g., X direction) with the central portion CR1 disposed therebetween. The first power/ground connection structures 115 may include first power connection structures 115P electrically connected to the power circuit pattern of the first semiconductor chip 110, first ground connection structures 115G electrically connected to the ground circuit pattern of the first semiconductor chip 110, and first dummy structures 115D electrically isolated from both the power circuit pattern and the ground circuit pattern of the first semiconductor chip 110.

For example, the first power/ground connection structures 115 may constitute first to third groups M1_, M1_2, and M1_3 in the first edge portion ER1_1 of the first semiconductor chip 110, and may constitute fourth to sixth groups M1_4, M1_5, and M1_6 in the second edge portion ER1_2 of the first semiconductor chip 110. In each of the first to sixth groups M1_1 to M1_6 of the first power/ground connection structures 115, the layout of the first power/ground connection structures 115 may have two or more rows and two or more columns. In each of the first to sixth groups M1_1 to M1_6 of the first power/ground connection structures 115, the first power/ground connection structures 115 may be spaced apart by a first pitch interval P1 in the first horizontal direction (e.g., X direction) and spaced apart by a second pitch interval P2 in the second horizontal direction (e.g., Y direction). The first pitch interval P1 and the second pitch interval P2 may be equal to or different from each other. Here, the first pitch interval P1 may be defined as a distance between the centers of two adjacent structures in the first horizontal direction (e.g., X direction), and the second pitch interval P2 may be defined as the distance between the centers of two adjacent structures in the second horizontal direction (e.g., Y direction). The first pitch interval P1 may be the same as a pitch interval between the first input/output connection structure 113H and the first input/output dummy structure 113D adjacent in the first horizontal direction (e.g., X direction) and a pitch interval between the second input/output connection structure 123H and the second input/output dummy structure 123D adjacent in the first horizontal direction (e.g., X direction) to be described below.

Each of the first to sixth groups M1_1 to M1_6 of the first power/ground connection structures 115 may have the same layout of the first power/ground connection structures 115. Here, having the same layout may mean that the type and order of structures constituting a specific row and column are the same. In each of the first to sixth groups M1_1 to M1_6 of the first power/ground connection structures 115, the number and arrangement of the first power connection structures 115P, the number and arrangement of the first ground connection structures 115G, and the number and arrangement of the first dummy structures 115D may be equal to each other.

The second semiconductor chip 120 may include a second semiconductor substrate 121, conductive second input/output channel structures 123 penetrating or extending into the second semiconductor substrate 121 in the vertical direction (e.g., Z direction), and conductive second power/ground connection structures 125 penetrating or extending into the second semiconductor substrate 121 in the vertical direction (e.g., Z direction). The second input/output channel structures 123 may be electrically and physically connected to the first input/output channel structures 113 through some of the third connection bumps 193, and the second power/ground connection structures 125 may be electrically and physically connected to the first power/ground connection structures 115 through the others of the third connection bumps 193. The second input/output channel structures 123 may be configured to transmit a second input/output channel signal (e.g., an input/output data signal, an address signal, and a clock signal) between the second semiconductor chip 120 and an external device. The second power/ground connection structures 125 may be configured to transmit a power signal and a ground signal to the second semiconductor chip 120 provided from the external device.

In some embodiments, the second input/output channel structures 123 may be disposed in a two-dimensional array in a central portion CR2 of the second semiconductor chip 120. That is, the layout of the second input/output channel structures 123 may have two or more rows and two or more columns. The second input/output channel structures 123 may include second input/output connection structures 123H and second input/output dummy structures 123D. The second input/output connection structures 123H may be electrically connected to the input/output circuit pattern of the second semiconductor chip 120. The second input/output dummy structures 123D may be electrically isolated from the input/output circuit pattern of the second semiconductor chip 120. In some embodiments, the second input/output connection structures 123H may be arranged in the second horizontal direction (e.g., Y direction) to constitute one column, and the second input/output dummy structures 123D may be arranged in the second horizontal direction (e.g., Y direction) to constitute one column. In this regard, the column of the second input/output connection structures 123H and the column of the second input/output dummy structures 123D may be spaced apart from each other in the second horizontal direction (e.g., Y direction). One second input/output connection structure 123H and one second input/output dummy structure 123D may be alternately disposed in one row of the second input/output channel structures 123.

In some embodiments, the second power/ground connection structures 125 may be respectively disposed in a first edge portion ER2_1 on one side (e.g., left side) of the central portion CR2 of the second semiconductor chip 120, and in a second edge portion ER2_2 on the other side (e.g., right side) of the central portion CR2 of the second semiconductor chip 120. The first edge portion ER2_1 and the second edge portion ER2_2 may be spaced apart from each other in the first horizontal direction (e.g., X direction) with the central portion CR2 disposed therebetween. The second power/ground connection structures 125 may include second power connection structures 125P electrically connected to the power circuit pattern of the second semiconductor chip 120, second ground connection structures 125G electrically connected to the ground circuit pattern of the second semiconductor chip 120, and second dummy structures 125D electrically isolated from both the power circuit pattern and the ground circuit pattern of the second semiconductor chip 120.

For example, the second power/ground connection structures 125 may constitute first to third groups M2_1, M2_2, and M2_3 in the first edge portion ER2_1 of the second semiconductor chip 120, and may constitute fourth to sixth groups M2_4, M2_5, and M2_6 in the second edge portion ER2_2 of the second semiconductor chip 120. In each of the first to sixth groups M2_1 to M2_6 of the second power/ground connection structures 125, the layout of the second power/ground connection structures 125 may have two or more rows and two or more columns. In each of the first to sixth groups M2_1 to M2_6 of the second power/ground connection structures 125, the second power/ground connection structures 125 may be spaced apart by the first pitch interval P1 in the first horizontal direction (e.g., X direction) and spaced apart by the second pitch interval P2 in the second horizontal direction (e.g., Y direction).

Each of the first to sixth groups M2_1 to M2_6 of the second power/ground connection structures 125 may have the same layout of the second power/ground connection structures 125. In each of the first to sixth groups M2_1 to M2_6 of the second power source/ground connection structures 125, the number and arrangement of the second power connection structures 125P, the number and arrangement of the second ground connection structures 125G, and the number and arrangement of the second dummy structures 125D may be equal to each other.

The second input/output connection structures 123H of the second semiconductor chip 120 may be aligned with the first input/output dummy structures 113D of the first semiconductor chip 110 in the vertical direction (e.g., Z direction), and may be electrically connected to the first input/output dummy structures 113D of the first semiconductor chip 110. The second input/output dummy structures 123D of the second semiconductor chip 120 may be aligned with the first input/output connection structures 113H of the first semiconductor chip 110 in the vertical direction (e.g., Z direction), and may be electrically connected to the first input/output connection structures 113H of the first semiconductor chip 110. The second input/output connection structures 123H of the second semiconductor chip 120 may be electrically connected to the second channel external connection terminals 220C2 through the first input/output dummy structures 113D of the first semiconductor chip 110 and the base substrate 210. The second semiconductor chip 120 and the external device may be configured to transmit/receive a second input/output channel signal through the second input/output connection structures 123H of the second semiconductor chip 120. Because the first input/output dummy structures 113D are electrically isolated from the input/output circuit pattern of the first semiconductor chip 110, the second input/output channel signal is not transmitted/received to/from the integrated circuits of the first semiconductor chip 110. The first input/output connection structures 113H of the first semiconductor chip 110 may be electrically connected to the first channel external connection terminals 220C1 through the base substrate 210. The first semiconductor chip 110 and the external device may be configured to transmit and receive the first input/output channel signal through the first input/output connection structures 113H of the first semiconductor chip 110. Because the second input/output dummy structures 123D are electrically isolated from the input/output circuit pattern of the second semiconductor chip 120, the first input/output channel signal is not transmitted/received to/from the integrated circuits of the second semiconductor chip 120.

The second power connection structures 125P of the second semiconductor chip 120 may be aligned with the first power connection structures 115P or the first dummy structures 115D of the first semiconductor chip 110 in the vertical direction (e.g., Z direction) and may be electrically connected to the first power connection structures 115P or the first dummy structures 115D of the first semiconductor chip 110. For example, some of the second power connection structures 125P of the second semiconductor chip 120 may be electrically connected to the first power connection structures 115P of the first semiconductor chip 110, and the others of the second power connection structures 125P of the second semiconductor chip 120 may be electrically connected to the first dummy structures 115D of the first semiconductor chip 110. Some of the second power connection structures 125P of the second semiconductor chip 120 may be electrically connected to some of the external power connection terminals 220P through the first power connection structures 115P of the first semiconductor chip 110 and the base substrate 210, and the others of the second power connection structures 125P of the second semiconductor chip 120 may be electrically connected to the others of the external power connection terminals 220P through the first dummy structures 115D of the first semiconductor chip 110 and the base substrate 210. The power signal provided from the external device may be provided to the second semiconductor chip 120 through the first power connection structures 115P and the second power connection structures 125P or through the first dummy structures 115D and the second power connection structures 125P. The first power connection structures 115P of the first semiconductor chip 110 may be electrically connected to the external power connection terminals 220P through the base substrate 210. The power signal provided from the external device may be provided to the first semiconductor chip 110 through the first power connection structures 115P.

The second ground connection structures 125G of the second semiconductor chip 120 may be aligned with the first ground connection structures 115G or the first dummy structures 115D of the first semiconductor chip 110 in the vertical direction (e.g., Z direction) and may be electrically connected to the first ground connection structures 115G or the first dummy structures 115D of the first semiconductor chip 110. For example, some of the second ground connection structures 125G of the second semiconductor chip 120 may be electrically connected to the first ground connection structures 115G of the first semiconductor chip 110, and the others of the second ground connection structures 125G of the second semiconductor chip 120 may be electrically connected to the first dummy structures 115D of the first semiconductor chip 110. Some of the second ground connection structures 125G of the second semiconductor chip 120 may be electrically connected to some of the ground external connection terminals 220G through the first ground connection structures 115G of the first semiconductor chip 110 and the base substrate 210, and the others of the second ground connection structures 125G of the second semiconductor chip 120 may be electrically connected to the others of the ground external connection terminals 220G through the first dummy structures 115D of the first semiconductor chip 110 and the base substrate 210. The ground signal provided from the external device may be provided to the second semiconductor chip 120 through the first ground connection structures 115G and the second ground connection structures 125G or through the first dummy structures 115D and the second ground connection structures 125G. The first ground connection structures 115G of the first semiconductor chip 110 may be electrically connected to the ground external connection terminals 220G through the base substrate 210. The ground signal provided from the external device may be provided to the first semiconductor chip 110 through the first ground connection structures 115G.

In some embodiments, the second semiconductor chip 120 may be rotationally symmetrical with the first semiconductor chip 110. For example, when the second semiconductor chip 120 rotates by 180° in a direction parallel to the vertical direction (e.g., Z direction), the first semiconductor chip 110 and the second semiconductor chip 120 may have a mirror symmetric structure with respect to a reference plane (e.g., XY plane). The layout of the second input/output channel structures 123 of the second semiconductor chip 120 may be rotationally symmetrical with the layout of the first input/output channel structures 113 of the first semiconductor chip 110, and the layout of the second power/ground connection structures 125 of the second semiconductor chip 120 may be rotationally symmetrical with the layout of the first power/ground connection structures 115 of the first semiconductor chip 110. For example, when the second semiconductor chip 120 rotates by 180° in the direction parallel to the vertical direction (e.g., Z direction), the layout of the second input/output channel structures 123 of the second semiconductor chip 120 may be mirror symmetrical with the layout of the first input/output channel structures 113 of the first semiconductor chip 110, and the layout of the second power/ground connection structures 125 of the second semiconductor chip 120 may be mirror symmetrical with the layout of the first power/ground connection structures 115 of the first semiconductor chip 110.

In some embodiments, in the layout of the first power/ground connection structures 115, the first ground connection structure 115G or the first dummy structure 115D may be disposed between the two first power connection structures 115P neighboring in the first horizontal direction (e.g., X direction) among the first power connection structures 115P and between the two first power connection structures 115P neighboring in the second horizontal direction (e.g., Y direction) among the first power connection structures 115P, and the first power connection structure 115P or the first dummy structure 115D may be disposed between the two first ground connection structures 115G neighboring in the first horizontal direction (e.g., X direction) among the first ground connection structures 115G and between the two first ground connection structures 115G neighboring in the second horizontal direction (e.g., Y direction) among the first ground connection structures 115G. In this case, in the layout of the first power/ground connection structures 115, the structures arranged in diagonal directions perpendicular to each of the first horizontal direction (e.g., X direction) and the second horizontal direction (e.g., Y direction) may be all the first power connection structures 115P, all the first ground connection structures 115G, combinations of the first power connection structures 115P and the first dummy structures 115D, or combinations of the first ground connection structures 115G and the first dummy structures 115D.

Even in the layout of the second power/ground connection structures 125 that are rotationally symmetrical with the layout of the second power/ground connection structures 125, the second ground connection structure 125G or the second dummy structure 125D may be disposed between the two second power connection structures 125P neighboring in the first horizontal direction (e.g., X direction) among the second power connection structures 125P and between the two second power connection structures 125P neighboring in the second horizontal direction (e.g., Y direction) among the second power connection structures 125P, and the second power connection structure 125P or the second dummy structure 125D may be disposed between the two second ground connection structures 125G neighboring in the first horizontal direction (e.g., X direction) among the second ground connection structures 125G and between the two first ground connection structures 125G neighboring in the second horizontal direction (e.g., Y direction) among the second ground connection structures 125G. In this case, in the layout of the second power/ground connection structures 125, the structures arranged in diagonal directions perpendicular to each of the first horizontal direction (e.g., X direction) and the second horizontal direction (e.g., Y direction) may be all the second power connection structures 125P, all the second ground connection structures 125G, combinations of the second power connection structures 125P and the second dummy structures 125D, or combinations of the second ground connection structures 125G and the second dummy structures 125D.

The semiconductor package 1000 may further include a molding layer disposed on the base substrate 210 and at least partially covering the first semiconductor chip 110 and the second semiconductor chip 120. The molding layer may be formed of, for example, an epoxy molding compound.

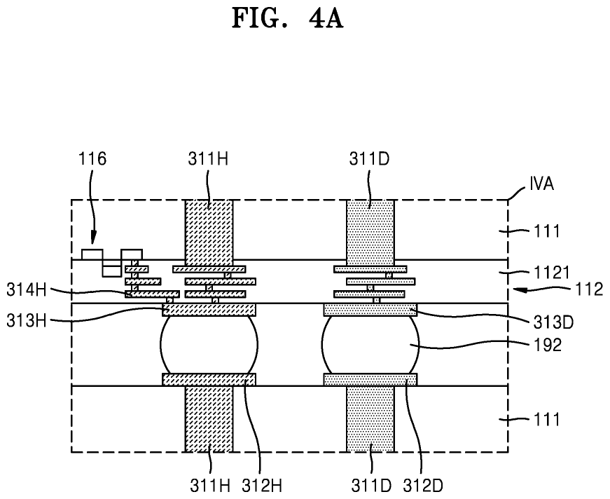

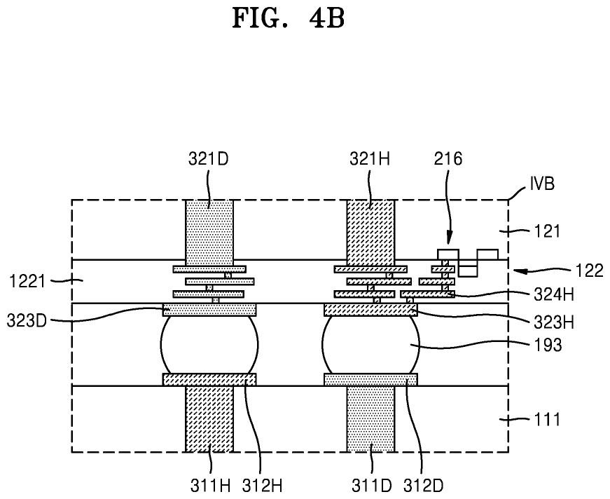

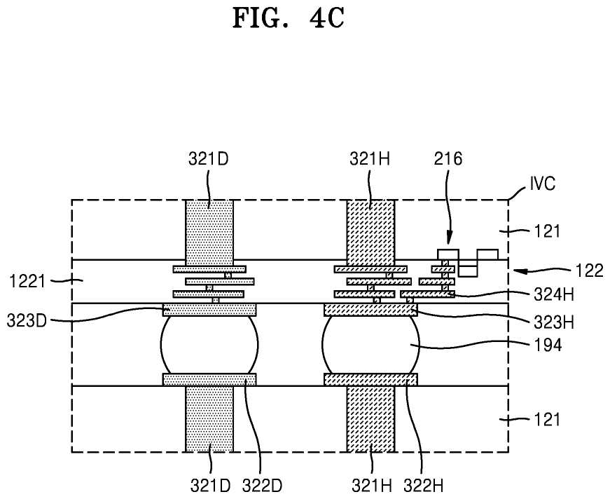

FIG. 4A is an enlarged view illustrating a portion indicated by “IVA” of FIG. 3. FIG. 4B is an enlarged view illustrating a portion indicated by “IVB” of FIG. 3. FIG. 4C is an enlarged view illustrating a portion indicated by “IVC” of FIG. 3.

Referring to FIGS. 4A to 4C together with FIGS. 1 to 3, the first semiconductor chip 110 may include a first semiconductor substrate 111 and a first semiconductor device layer 112. The first semiconductor substrate 111 may include upper and lower surfaces opposite to each other. The lower surface of the first semiconductor substrate 111 may be an active surface of the first semiconductor substrate 111, and the upper surface of the first semiconductor substrate 111 may be an inactive surface of the first semiconductor substrate 111. The first semiconductor substrate 111 may be formed from a semiconductor wafer. The first semiconductor substrate 111 may include, for example, silicon (Si). The first semiconductor device layer 112 may be formed on the lower surface of the first semiconductor substrate 111. The first semiconductor device layer 112 may include a first integrated circuit 116, wirings, and a first insulating layer 1121. The first integrated circuit 116 may include, for example, a memory circuit, a logic circuit, and/or a combination thereof.

The first input/output connection structure 113H may include a first input/output through electrode 311H penetrating or extending into the first semiconductor substrate 111 in the vertical direction (e.g., Z direction), a first input/output upper pad 312H provided on the upper surface of the first semiconductor substrate 111 and connected to an upper portion of the first input/output through electrode 311H, and a first input/output lower pad 313H disposed below the lower surface of the first semiconductor substrate 111 and electrically connected to a lower portion of the first input/output through electrode 311H. The first input/output connection structure 113H may be electrically connected to the first integrated circuit 116 through the first input/output circuit pattern 314H provided on the first semiconductor device layer 112.

The first input/output dummy structure 113D may include a first input/output dummy through electrode 311D penetrating or extending into the first semiconductor substrate 111 in the vertical direction (e.g., Z direction), a first input/output dummy upper pad 312D provided on the upper surface of the first semiconductor substrate 111 and connected to an upper portion of the first input/output dummy through electrode 311D, and a first input/output dummy lower pad 313D disposed below the lower surface of the first semiconductor substrate 111 and electrically connected a lower portion of the first input/output dummy through electrode 311D. The first input/output dummy structure 113D may be electrically isolated from the first input/output circuit pattern 314H and the first integrated circuit 116.

In a plan view, each of the first input/output through electrode 311H, the first input/output upper pad 312H, the first input/output lower pad 313H, the first input/output dummy through electrode 311D, the first input/output dummy upper pad 312D, and the first input/output dummy lower pad 313D may have a polygonal shape such as a circle or a square.

The second semiconductor chip 120 may include a second semiconductor substrate 121 and a second semiconductor device layer 122. The second semiconductor substrate 121 may include upper and lower surfaces opposite to each other. The lower surface of the second semiconductor substrate 121 may be an active surface of the second semiconductor substrate 121, and the upper surface of the second semiconductor substrate 121 may be an inactive surface of the second semiconductor substrate 121. The material of the second semiconductor substrate 121 may be the same as that of the first semiconductor chip 110. The second semiconductor device layer 122 may be formed on the lower surface of the second semiconductor substrate 121. The second semiconductor device layer 122 may include a second integrated circuit 216, wirings, and a second insulating layer 1221. The second integrated circuit 216 may include the same type of integrated circuit as the first integrated circuit 116.

The second input/output connection structure 123H may include a second input/output through electrode 321H penetrating or extending into the second semiconductor substrate 121 in the vertical direction (e.g., Z direction), a second input/output upper pad 322H provided on the upper surface of the second semiconductor substrate 121 and connected to an upper portion of the second input/output through electrode 321H, and a second input/output lower pad 323H disposed below the lower surface of the second semiconductor substrate 121 and electrically connected a lower portion of the second input/output through electrode 321H. The second input/output connection structure 123H may be electrically connected to a second power circuit pattern 344P provided on the second semiconductor device layer 122. The second input/output connection structure 123H may be electrically connected to the second integrated circuit 216 through the second input/output circuit pattern 324H provided on the second semiconductor device layer 122.

The second input/output dummy structure 123D may include a second input/output dummy through electrode 321D penetrating or extending into the second semiconductor substrate 121 in the vertical direction (e.g., Z direction), a second input/output dummy upper pad 322D provided on the upper surface of the second semiconductor substrate 121 and connected to an upper portion of the second input/output dummy through electrode 321D, and a second input/output dummy lower pad 323D disposed below the lower surface of the second semiconductor substrate 121 and electrically connected to a lower portion of the second input/output dummy through electrode 321D. The second input/output dummy structure 123D may be electrically isolated from the second input/output circuit pattern 324H and the second integrated circuit 216.

In a plan view, each of the second input/output through electrode 321H, the second input/output upper pad 322H, the second input/output lower pad 323H, the second input/output dummy through electrode 321D, the second input/output dummy upper pad 322D, and the second input/output dummy lower pad 323D may have a polygonal shape such as a circle or a square.

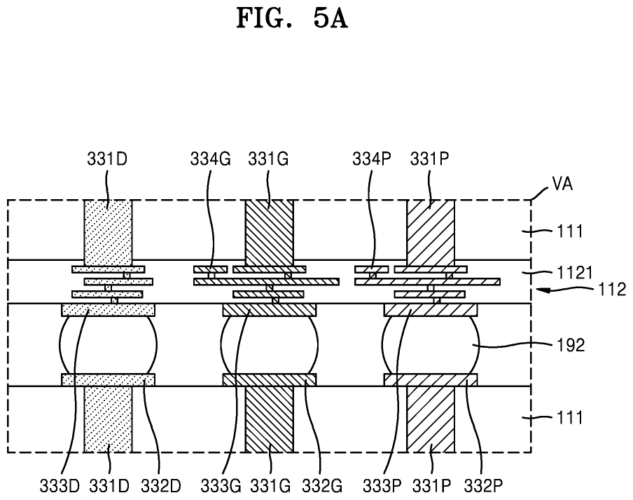

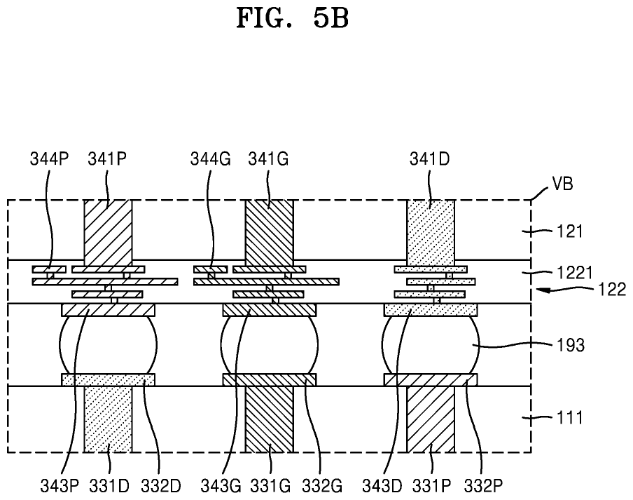

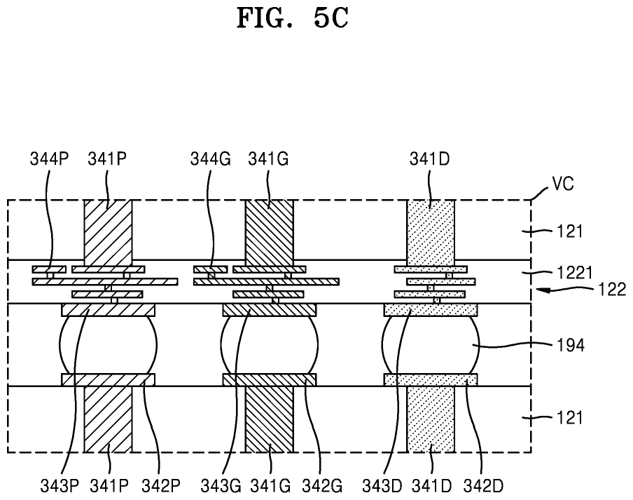

FIG. 5A is an enlarged view illustration a portion indicated by “VA” of FIG. 3. FIG. 5B is an enlarged view illustration a portion indicated by “VB” of FIG. 3. FIG. 5C is an enlarged view illustration a portion indicated by “VC” in FIG. 3.

Referring to FIGS. 5A to 5C together with FIGS. 1 to 3, the first power connection structure 115P may include a first power through electrode 331P penetrating or extending into the first semiconductor substrate 111 in the vertical direction (e.g., Z direction), a first power upper pad 332P provided on the upper surface of the and the first semiconductor substrate 111 and connected to an upper portion of the first power through electrode 331P, and a first power lower pad 333P disposed below the lower surface of the first semiconductor substrate 111 and electrically connected to a lower portion of the first power through electrode 331P. The first power connection structure 115P may be electrically connected to a first power circuit pattern 334P provided on the first semiconductor device layer 112. A power signal provided from the outside may be provided to individual devices provided in the first semiconductor chip 110 such as the first integrated circuit 116 through the first power connection structure 115P and the first power circuit pattern 334P.

The first ground connection structure 115G may include a first ground through electrode 331G penetrating or extending into the first semiconductor substrate 111 in the vertical direction (e.g., Z direction), a first ground upper pad 332G provided on the upper surface of the and the first semiconductor substrate 111 and connected to an upper portion of the first ground through electrode 331G, and a first ground lower pad 333G disposed below the lower surface of the first semiconductor substrate 111 and electrically connected to a lower portion of the first ground through electrode 331G. The first ground connection structure 115G may be electrically connected to the first ground circuit pattern 334G provided in the first semiconductor device layer 112. A ground signal provided from the outside may be provided to individual devices provided in the first semiconductor chip 110, such as the first integrated circuit 116 through the first ground connection structure 115G and the first ground circuit pattern 334G.

The first dummy structure 115D may include a first dummy through electrode 331D penetrating or extending into the first semiconductor substrate 111 in the vertical direction (e.g., Z direction), a first dummy upper pad 332D provided on the upper surface of the first semiconductor substrate 111 and connected to an upper portion of the first dummy through electrode 311D, and a first dummy lower pad 333D disposed below the lower surface of the first semiconductor substrate 111 and electrically connected a lower portion of the first dummy through electrode 311D. The first dummy structure 115D may be electrically isolated from the first power circuit pattern 334P and the first ground circuit pattern 334G.

In a plan view, each of the first power through electrode 331P, the first power upper pad 332P, the first power lower pad 333P, the first ground through electrode 331G, the first ground upper pad 332G, the first ground lower pad 333G, the first dummy through electrode 331D, the first dummy upper pad 332D, and the first dummy lower pad 333D may have a polygonal shape such as a circle or a square.

The second power connection structure 125P may include a second power through electrode 341P penetrating or extending into the second semiconductor substrate 121 in the vertical direction (e.g., Z direction), a second power upper pad 342P provided on the upper surface of the second semiconductor substrate 121 and connected to an upper portion of the second power through electrode 341P, and a second power lower pad 343P disposed below the lower surface of the second semiconductor substrate 121 and electrically connected a lower portion of the second power through electrode 341P. The second power connection structure 125P may be electrically connected to the second power circuit pattern 344P provided on the second semiconductor device layer 122. A power signal provided from the outside may be provided to individual devices provided in the second semiconductor chip 120 such as the second integrated circuit 216 through the second power connection structure 125P and the second power circuit pattern 344P.

The second ground connection structure 125G may include a second ground through electrode 341G penetrating or extending into the second semiconductor substrate 121 in the vertical direction (e.g., Z direction), a second ground upper pad 342G provided on the upper surface of the second semiconductor substrate 121 and connected to an upper portion of the second ground through electrode 341G, and a second ground lower pad 343G disposed below the lower surface of the second semiconductor substrate 121 and electrically connected to a lower portion of the second ground through electrode 341G. The second ground connection structure 125G may be electrically connected to the second ground circuit pattern 344G provided in the second semiconductor device layer 122. A ground signal provided from the outside may be provided to individual devices provided in the second semiconductor chip 120 such as the second integrated circuit 216 through the second ground connection structure 125G and the second ground circuit pattern 344G.

The second dummy structure 125D may include a second dummy through electrode 341D penetrating or extending into the second semiconductor substrate 121 in the vertical direction (e.g., Z direction), a second dummy upper pad 342D provided on the upper surface of the second semiconductor substrate 121 and connected to an upper portion of the second dummy through electrode 341D, and a second dummy lower pad 343D disposed below the lower surface of the second semiconductor substrate 121 and electrically connected to a lower portion of the second dummy through electrode 341D. The second dummy structure 125D may be electrically isolated from the second power circuit pattern 344P and the second ground circuit pattern 344G.

In a plan view, each of the second power through electrode 341P, the second power upper pad 342P, the second power lower pad 343P, the second ground through electrode 341G, the second ground upper pad 342G, the second ground lower pad 343G, the second dummy through electrode 341D, the second dummy upper pad 342D, and the second dummy lower pad 343D may have a polygonal shape such as a circle or a square.

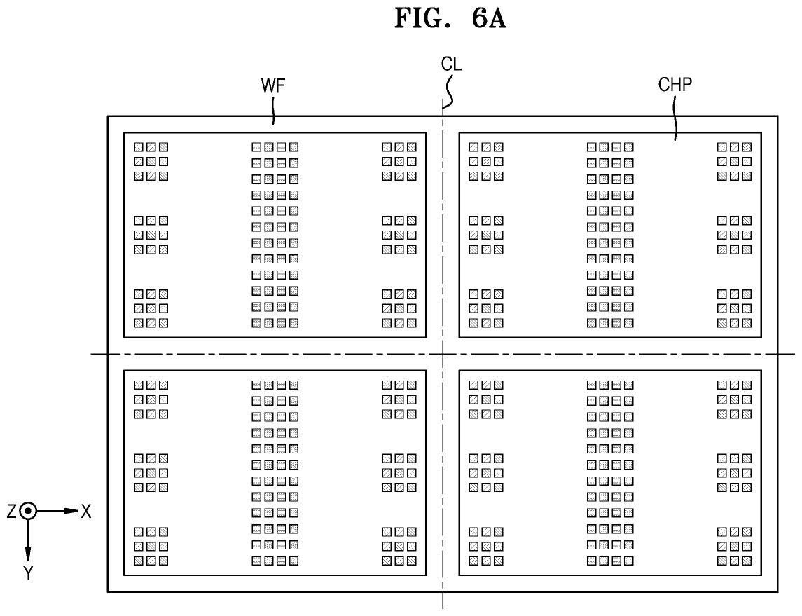

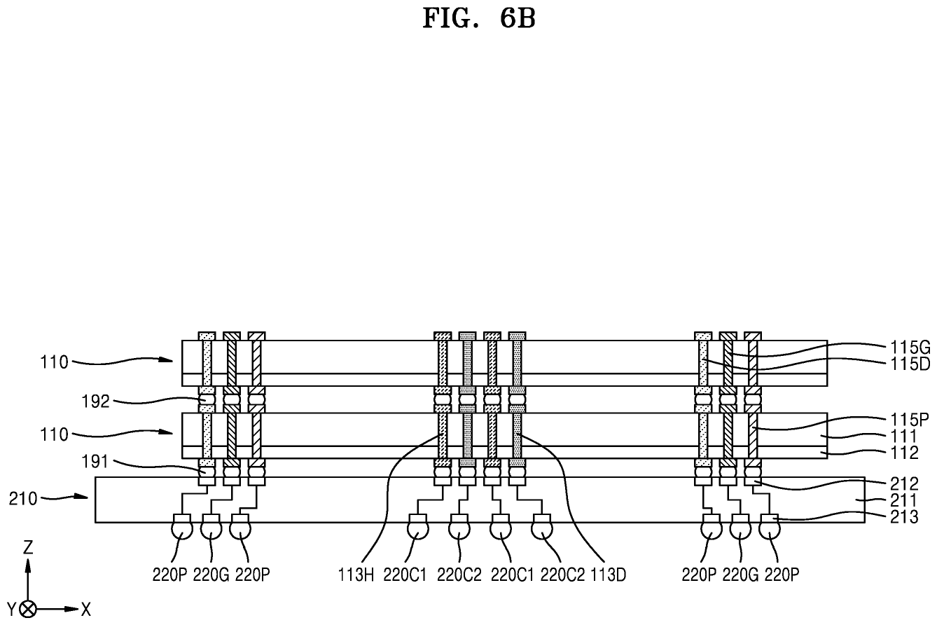

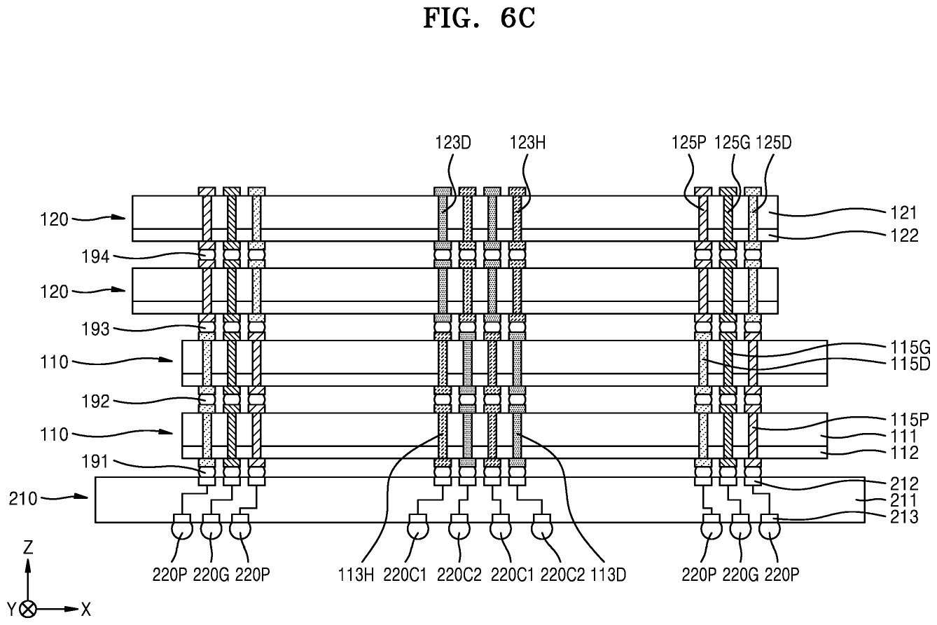

FIGS. 6A to 6C are diagrams illustrating a method of manufacturing a semiconductor package, according to some embodiments. Hereinafter, the method of manufacturing the semiconductor package 1000 described with reference to FIGS. 1 to 3 is described with reference to FIGS. 6A to 6C.

Referring to FIG. 6A, a semiconductor wafer WF on which semiconductor chips CHP are formed is prepared. The semiconductor chips CHP may have the same structure and may be configured to perform the same function. The semiconductor wafer WF may be separated into the plurality of semiconductor chips CHP, by cutting a cutting line CL of the semiconductor wafer WF. The semiconductor chips CHP may correspond to the first semiconductor chip 110 and the second semiconductor chip 120 illustrated in FIGS. 1 to 3.

Referring to FIG. 6B, the two first semiconductor chips 110 oriented in the same direction are sequentially mounted on the base substrate 210. The lower first semiconductor chip 110 among the two first semiconductor chips 110 may be mounted on the base substrate 210 through the first connection bumps 191, and the upper first semiconductor chip 110 among the two first semiconductor chips 110 may be mounted on the base substrate 210 may be mounted on the lower first semiconductor chip 110 through the second connection bumps 192.

Referring to FIGS. 6A and 6C, the two second semiconductor chips 120 oriented in the same direction are sequentially mounted on the upper first semiconductor chip 110. The second semiconductor chip 120 may be oriented to be rotationally symmetrical with the first semiconductor chip 110. For example, when the first semiconductor chip 110 forms a first angle with respect to a predetermined reference direction, the second semiconductor chip 120 may form a second angle that is the sum of the first angle and 180° with respect to the reference direction. The lower first semiconductor chip 110 among the two first semiconductor chips 110 may be mounted on the upper first semiconductor chip 110 through the third connection bumps 193, and the upper second semiconductor chip 120 among the two second semiconductor chips 120 may be mounted on the lower second semiconductor chip 120 through the fourth connection bumps 194. The second semiconductor chip 120 may be offset in a lateral direction and stacked on the first semiconductor chip 110 so that the second input/output channel structures 123 are respectively connected to the corresponding first input/output channel structures 113, and the second power/ground connection structures 125 are respectively connected to the corresponding first power/ground connection structures 115.

After the second semiconductor chip 120 is mounted on the first semiconductor chip 110, a molding process may be performed to form a molding layer at least partially covering the first semiconductor chips 110 and the second semiconductor chips 120 on the base substrate 210.

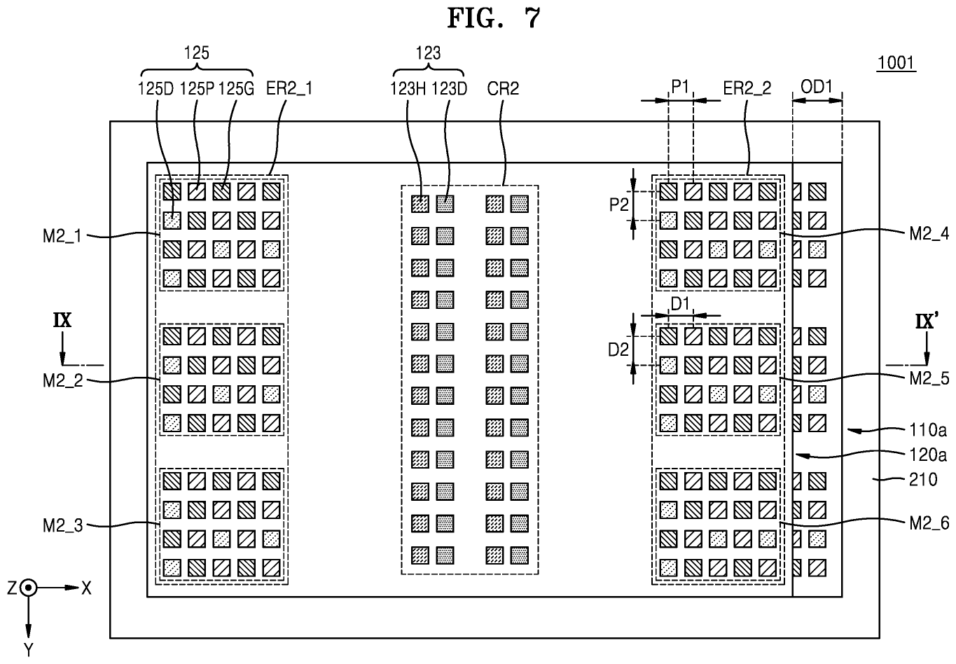

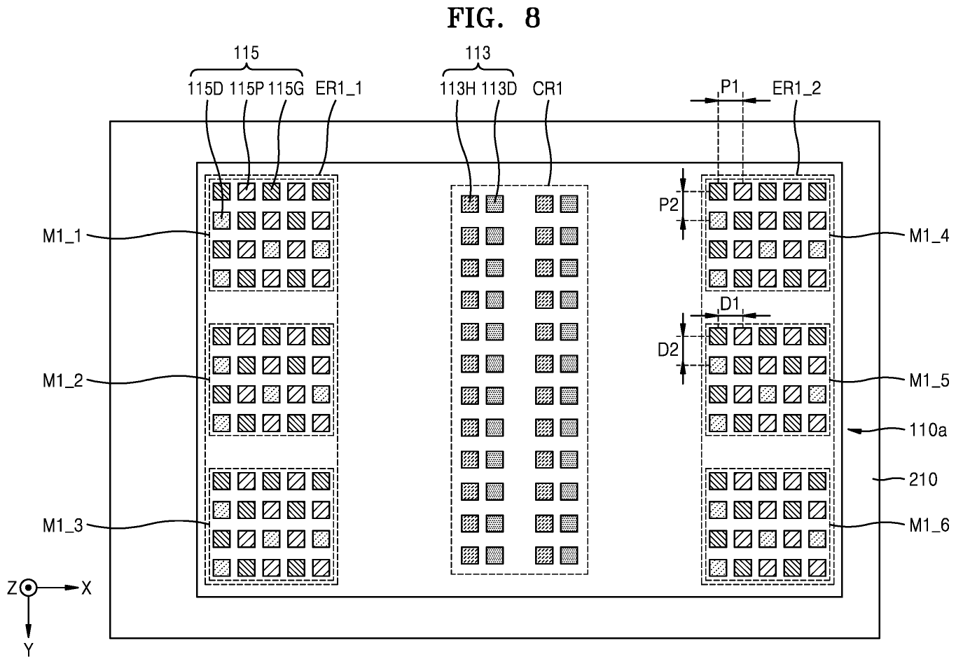

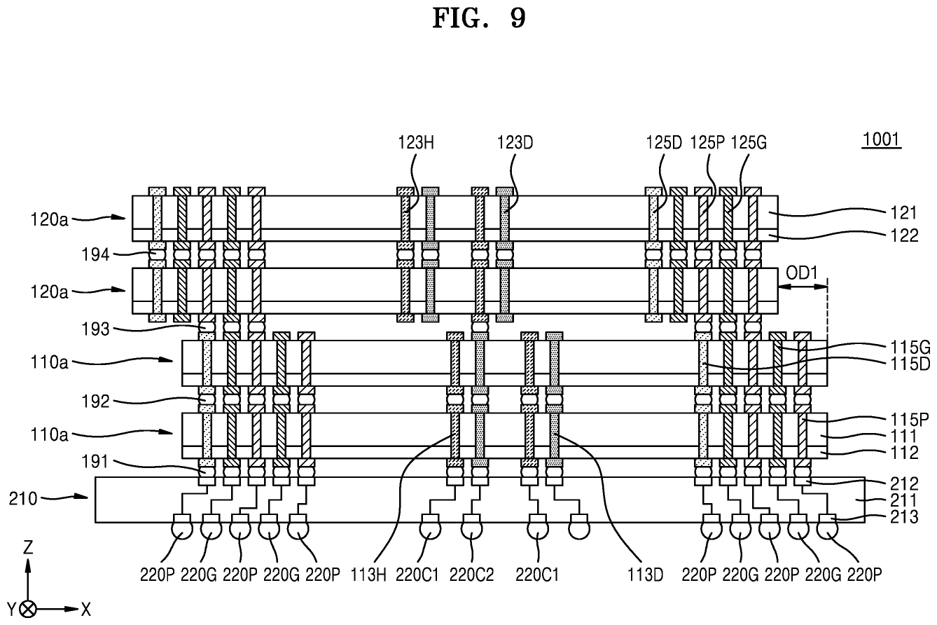

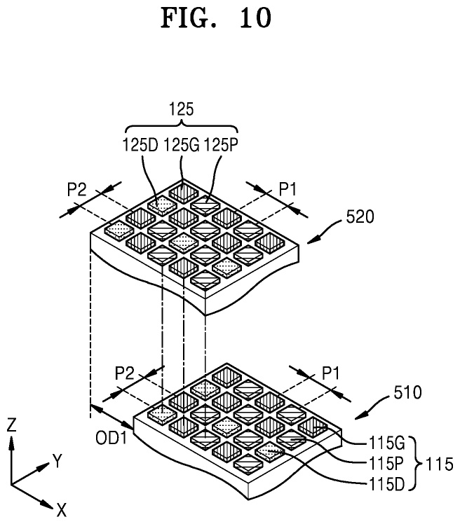

FIG. 7 is a plan view illustrating a semiconductor package 1001 according to some embodiments. FIG. 8 is a plan view illustrating a first semiconductor chip 110a illustrated in FIG. 7. FIG. 9 is a cross-sectional view taken along line IX-IX′ of FIG. 7. FIG. 10 is a perspective view schematically illustrating a layout 510 of the first power/ground connection structures 115 of the first semiconductor chip 110a and a layout 520 of the second power/ground connection structures 125 of the second semiconductor chip 120a shown in FIG. 7.

Hereinafter, the semiconductor package 1001 illustrated in FIGS. 7 to 10 is described with respect to differences from the semiconductor package 1000 described with reference to FIGS. 1 to 3.

Referring to FIGS. 7 to 10, in the layout 510 of the first power/ground connection structures 115, any one of the first ground connection structures 115G or any one of the first dummy structures 115D may be disposed between the two first power connection structures 115P neighboring in the first horizontal direction (e.g., X direction) among the first power connection structures 115P and between the two first power connection structures 115P neighboring in the second horizontal direction (e.g., Y direction) among the first power connection structures 115P, and any one of the first power connection structures 115P or any one of the first dummy structures 115D may be disposed between the two first ground connection structures 115G neighboring in the first horizontal direction (e.g., X direction) among the first ground connection structures 115G and between the two first ground connection structures 115G neighboring in the second horizontal direction (e.g., Y direction) among the first ground connection structures 115G.

In some embodiments, in the layout 510 of the first power/ground connection structures 115, two structures spaced apart by a first distance D1 in the first horizontal direction (e.g., X direction) may be different types of structures, and two structures spaced apart by a second distance D2 in the second horizontal direction (e.g., Y direction) may be different types of structures. The first distance D1 may be N times (N is a natural number) of the first pitch interval P1, and the second distance D2 may be M times (M is a natural number) of the second pitch interval P2. The first distance D1 may mean a distance between the centers of the two corresponding structures in the first horizontal direction (e.g., X direction), and the second distance D2 may mean a distance between the centers of the two corresponding structures in the second horizontal direction (e.g., Y direction).

In FIGS. 7 to 10, the first distance D1 is an odd multiple of the first pitch interval P1, and the second distance D2 is an odd multiple of the second pitch interval P2. For example, a structure at the first distance D1 equal to the first pitch interval P1 in the first horizontal direction (e.g., X direction) and a structure at the second distance D2 equal to the second pitch interval P2 in the second horizontal direction (e.g., Y direction) from the first power connection structure 115P may be the first ground connection structure 115G or the first dummy structure 115D. For example, a structure at the first distance D1 equal to the first pitch interval P1 in the first horizontal direction (e.g., X direction) and a structure at the second distance D2 equal to the second pitch interval P2 in the second horizontal direction (e.g., Y direction) from the first ground connection structure 115G may be the first power connection structure 115P or the first dummy structure 115D.

The layout 520 of the second power/ground connection structures 125 of the second semiconductor chip 120a and the layout 510 of the first power/ground connection structures 115 of the first semiconductor chip 110a may be identical to each other.

In the layout 520 of the second power/ground connection structures 125, any one of the second ground connection structure 125G or any one of the second dummy structure 125D may be disposed between the two second power connection structures 125P neighboring in the first horizontal direction (e.g., X direction) among the second power connection structures 125P and between the two second power connection structures 125P neighboring in the second horizontal direction (e.g., Y direction) among the second power connection structures 125P, and any one of the second power connection structure 125P or any one of the second dummy structure 125D may be disposed between the two second ground connection structures 125G neighboring in the first horizontal direction (e.g., X direction) among the second ground connection structures 125G and between the two first ground connection structures 125G neighboring in the second horizontal direction (e.g., Y direction) among the second ground connection structures 125G.

In some embodiments, in the layout 520 of the second power/ground connection structures 125, two structures spaced apart by the first distance D1 in the first horizontal direction (e.g., X direction) may be different types of structures, and two structures spaced apart by the second distance D2 in the second horizontal direction (e.g., Y direction) may be different types of structures. For example, a structure at the first distance D1 in the first horizontal direction (e.g., X direction) and a structure at the second distance D2 in the second horizontal direction (e.g., Y direction) from the second power connection structure 125P may be the second ground connection structure 125G or the second dummy structure 125D. For example, a structure at the first distance D1 in the first horizontal direction (e.g., X direction) and a structure at the second distance D2 in the second horizontal direction (e.g., Y direction) from the second ground connection structure 125G may be the second power connection structure 125P or the second dummy structure 125D.

The second semiconductor chip 120a may be stacked on the first semiconductor chip 110a in an offset stack. For example, the second semiconductor chip 120a may be offset in the first horizontal direction (e.g., X direction) and stacked on the first semiconductor chip 110, and a part of the second semiconductor chip 120a may protrude from the first semiconductor chip 110 in the first horizontal direction (e.g., X direction).

In some embodiments, an offset distance OD1, which is a distance at which the second semiconductor chip 120a is offset in the first horizontal direction (e.g., X direction) from the edge of the first semiconductor chip 110a may be an even multiple of the pitch interval P1. For example, the offset distance OD1 may be twice the first pitch interval P1. In this case, the second input/output connection structures 123H may be electrically connected to the base substrate 210 through the first input/output connection structures 113H or the first input/output dummy structures 113D. In addition, the second power connection structures 125P may be electrically connected to the base substrate 210 through the first power connection structures 115P or the first dummy structures 115D, and the second ground connection structures 125G may be electrically connected to the base substrate 210 through the first ground connection structures 115G or the first dummy structures 115D.

When the second semiconductor chip 120a is offset in the first horizontal direction (e.g., X direction) from the edge of the first semiconductor chip 110a, some of the second power/ground connection structures 125 may not be connected to the first power/ground connection structures 115. In some embodiments, to sufficiently supply a power signal and a ground signal to the second semiconductor chip 120a, more than half of the second power connection structures 125P may be electrically connected to the base substrate 210 through the first power connection structures 115P or the first dummy structures 115D, and more than half of the second ground connection structures 125G may be electrically connected to the base substrate 210 through the first ground connection structures 115G or the first dummy structures 115D.

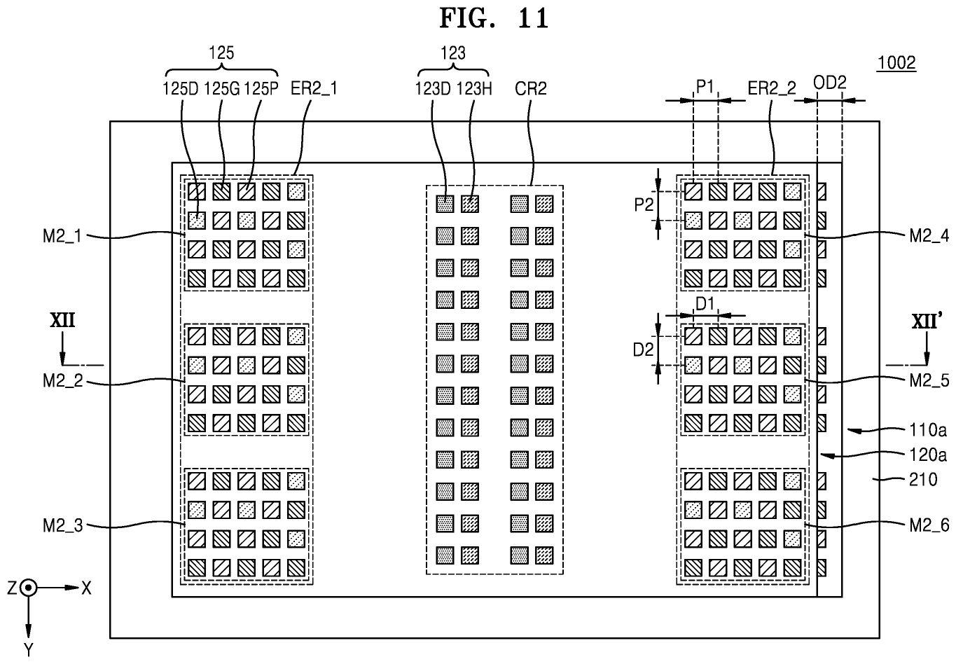

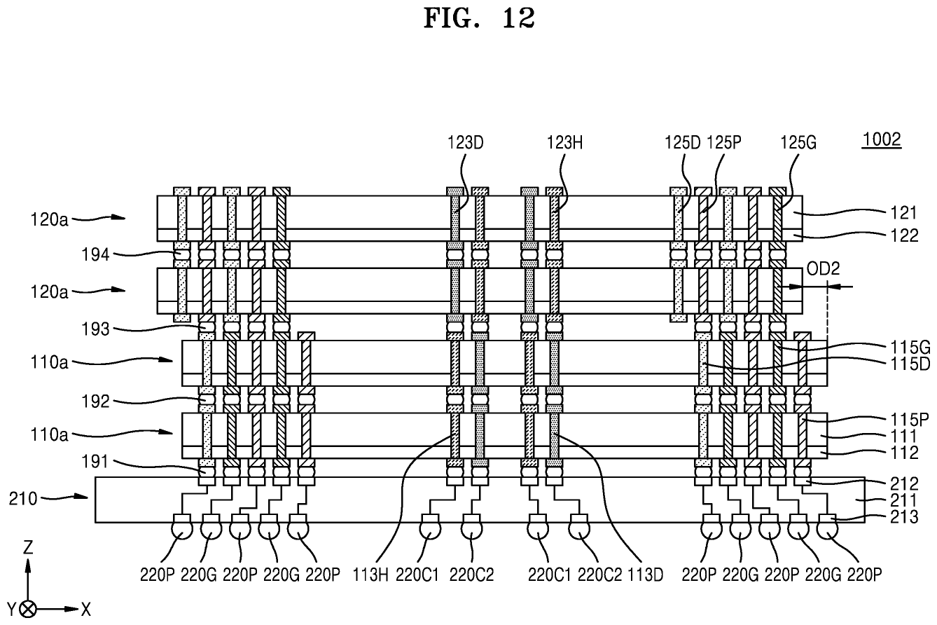

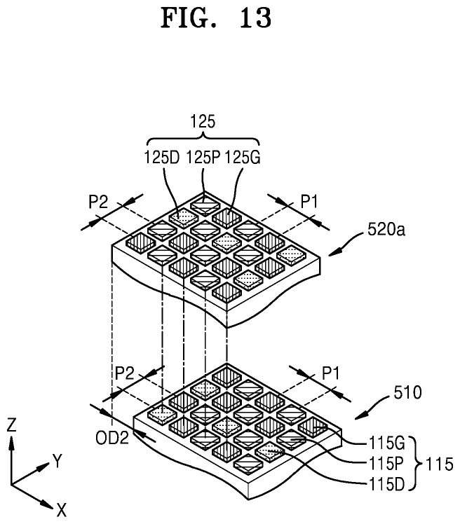

FIG. 11 is a plan view illustrating a semiconductor package 1002 according to some embodiments. FIG. 12 is a cross-sectional view taken along line XII-XII′ of FIG. 11. FIG. 13 is a perspective view schematically illustrating a layout 510 of the first power/ground connection structures 115 of the first semiconductor chip 110a and a layout 520a of the second power/ground connection structures 125 of the second semiconductor chip 120a shown in FIG. 11. Hereinafter, the semiconductor package 1002 shown in FIGS. 11 to 13 is described with respect to differences from the semiconductor package 1001 described with reference to FIGS. 7 to 10.

Referring to FIGS. 11 to 13, the second semiconductor chip 120a may be rotationally symmetrical with the first semiconductor chip 110a. For example, when the second semiconductor chip 120a rotates by 180° in a direction parallel to the vertical direction (e.g., Z direction), the first semiconductor chip 110a and the second semiconductor chip 120a may have a mirror symmetric structure with respect to a reference plane (e.g., XY plane) parallel to the first horizontal direction (e.g., X direction) and the second horizontal direction (e.g., Y direction). The layout 510 of the first power/ground connection structures 115 of the first semiconductor chip 110a may be the same as the layout 510 of the first power/ground connection structures 115 of the first semiconductor chip 110a illustrated in FIGS. 7 to 10, and the layout 520a of the first power/ground connection structures 115 of the second semiconductor chip 120a may be rotationally symmetrical with the layout 520 of the second power/ground connection structures 125 of the second semiconductor chip 120a illustrated in FIGS. 7 to 10.

In some embodiments, the second semiconductor chip 120a may be stacked on the first semiconductor chip 110a in an offset stack and may be rotationally symmetrical with the first semiconductor chip 110a. An offset distance OD2, which is a distance at which the second semiconductor chip 120a is offset in the first horizontal direction (e.g., X direction) from the edge of the first semiconductor chip 110a may be an odd multiple of the first pitch interval P1. For example, the offset distance OD2 may be one time the first pitch interval P1. In this case, the second input/output connection structures 123H may be electrically connected to the base substrate 210 through the first input/output connection structures 113H or the first input/output dummy structures 113D. In addition, the second power connection structures 125P may be electrically connected to the base substrate 210 through the first power connection structures 115P or the first dummy structures 115D, and the second ground connection structures 125G may be electrically connected to the base substrate 210 through the first ground connection structures 115G or the first dummy structures 115D.

When the second semiconductor chip 120a is offset in the first horizontal direction (e.g., X direction) from the edge of the first semiconductor chip 110a, some of the second power/ground connection structures 125 may not be connected to the first power/ground connection structures 115. In some embodiments, to sufficiently supply a power signal and a ground signal to the second semiconductor chip 120a, more than half of the second power connection structures 125P may be electrically connected to the base substrate 210 through the first power connection structures 115P or the first dummy structures 115D, and more than half of the second ground connection structures 125G may be electrically connected to the base substrate 210 through the first ground connection structures 115G or the first dummy structures 115D.

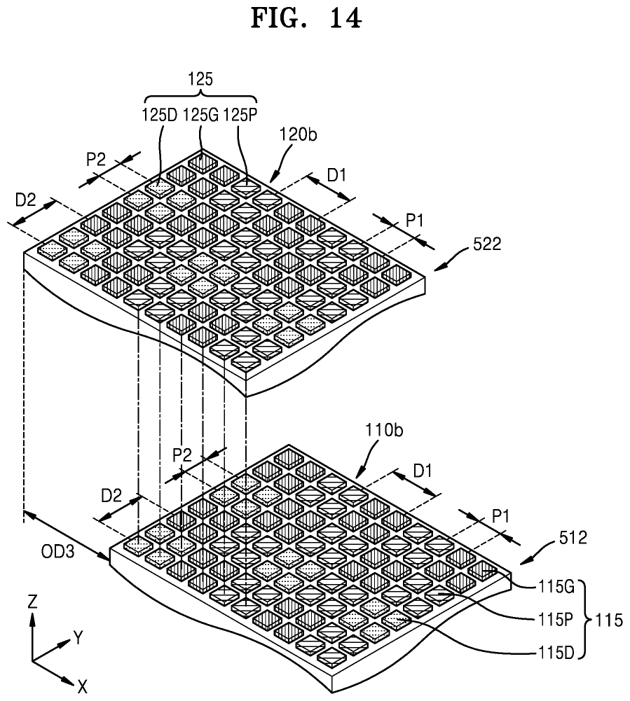

FIG. 14 is a perspective view schematically illustrating a part of a semiconductor package according to some embodiments, that is, a layout 512 of the first power/ground connection structures 115 of the first semiconductor chip 110b and a layout 522 of the second power/ground connection structures 125 of a second semiconductor chip 120b. Hereinafter, the semiconductor package shown in FIG. 14 is described with respect to differences from the semiconductor package 1001 described with reference to FIGS. 7 to 10.

Referring to FIG. 14, in the layout 512 of the first power/ground connection structures 115, two structures spaced apart by the first distance D1 in the first horizontal direction (e.g., X direction) may be different types of structures, and two structures spaced apart by the second distance D2 in the second horizontal direction (e.g., Y direction) may be different types of structures. The first distance D1 may be N times (N is a natural number) of the first pitch interval P1, and the second distance D2 may be M times (M is a natural number) of the second pitch interval P2. In FIG. 14, the first distance D1 may be twice the first pitch interval P1, and the second distance D2 may be twice the second pitch interval P2. For example, a structure at the first distance D1 in the first horizontal direction (e.g., X direction) and a structure at the second distance D2 in the second horizontal direction (e.g., Y direction) from the first power connection structure 115P may be the first ground connection structure 115G or the first dummy structure 115D. For example, a structure at the first distance D1 in the first horizontal direction (e.g., X direction) and a structure at the second distance D2 in the second horizontal direction (e.g., Y direction) from the first ground connection structure 115G may be the first power connection structure 115P or the first dummy structure 115D.

In some embodiments, each of one row and one column of the layout 512 of the first power/ground connection structures 115 may include P (P is a natural number equal to or greater than 2) continuously arranged first power connection structures 115P, P continuously arranged first ground connection structures 115G, and/or P continuously arranged first dummy structures 115D. In this case, the first distance D1 may be P times the first pitch interval P1, and the second distance D2 may be P times the second pitch interval P2. For example, FIG. 14 shows that each of one row and one column of the layout 512 of the first power/ground connection structures 115 includes two continuously arranged first power connection structures 115P, two continuously arranged first ground connection structures 115G, and/or two continuously arranged first dummy structures 115D. In this case, the first distance D1 may be twice the first pitch interval P1 and the second distance D2 may be twice the second pitch interval P2.

The layout 522 of the second power/ground connection structures 125 of the second semiconductor chip 120b and the layout 512 of the first power/ground connection structures 115 of the first semiconductor chip 110b may be identical to each other.

In some embodiments, in the layout 520 of the second power/ground connection structures 125, two structures spaced apart by the first distance D1 in the first horizontal direction (e.g., X direction) may be different types of structures, and two structures spaced apart by the second distance D2 in the second horizontal direction (e.g., Y direction) may be different types of structures. The first distance D1 may be N times (N is a natural number) of the first pitch interval P1, and the second distance D2 may be M times (M is a natural number) of the second pitch interval P2. In FIG. 14, the first distance D1 may be twice the first pitch interval P1, and the second distance D2 may be twice the second pitch interval P2. For example, a structure at the first distance D1 in the first horizontal direction (e.g., X direction) and a structure at the second distance D2 in the second horizontal direction (e.g., Y direction) from the second power connection structure 125P may be the second ground connection structure 125G or the second dummy structure 125D. For example, a structure at the first distance D1 in the first horizontal direction (e.g., X direction) and a structure at the second distance D2 in the second horizontal direction (e.g., Y direction) from the second ground connection structure 125G may be the second power connection structure 125P or the second dummy structure 125D.

In some embodiments, each of one row and one column of the layout 522 of the second power/ground connection structures 125 may include P (P is a natural number equal to or greater than 2) continuously arranged second power connection structures 125P, P continuously arranged second ground connection structures 125G, and/or P continuously arranged second dummy structures 125D. In this case, the first distance D1 may be P times the first pitch interval P1, and the second distance D2 may be P times the second pitch interval P2. For example, FIG. 14 shows that each of one row and one column of the layout 522 of the second power/ground connection structures 125 may include two continuously arranged second power connection structures 125P, two continuously arranged second ground connection structures 125G, and/or two continuously arranged second dummy structures 125D. In this case, the first distance D1 may be twice the first pitch interval P1 and the second distance D2 may be twice the second pitch interval P2.

The second semiconductor chip 120b may be stacked on the first semiconductor chip 110b in an offset stack. For example, the second semiconductor chip 120b may be offset in the first horizontal direction (e.g., X direction) and stacked on the first semiconductor chip 110, and a part of the second semiconductor chip 120b may protrude from the first semiconductor chip 110 in the first horizontal direction (e.g., X direction).

In some embodiments, an offset distance OD3, which is a distance at which the second semiconductor chip 120b is offset in the first horizontal direction (e.g., X direction) from the edge of the first semiconductor chip 110a may be an even multiple of the first distance D1. For example, the offset distance OD3 may be twice the first distance D1. In this case, the second input/output connection structures 123H may be electrically connected to the base substrate 210 through the first input/output connection structures 113H or the first input/output dummy structures 113D. In addition, the second power connection structures 125P may be electrically connected to the base substrate 210 through the first power connection structures 115P or the first dummy structures 115D, and the second ground connection structures 125G may be electrically connected to the base substrate 210 through the first ground connection structures 115G or the first dummy structures 115D.

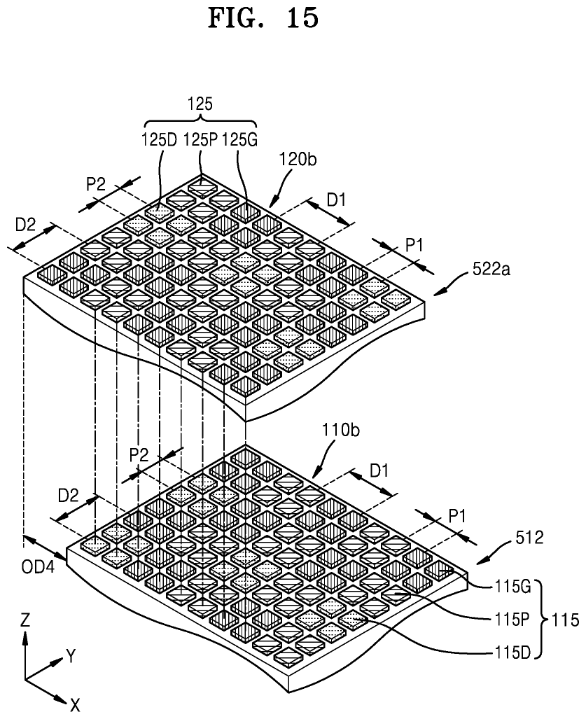

FIG. 15 is a perspective view schematically illustrating a part of a semiconductor package according to some embodiments, that is, the layout 512 of the first power/ground connection structures 115 of the first semiconductor chip 110b and the layout 522 of the second power/ground connection structures 125 of the second semiconductor chip 120b. Hereinafter, the semiconductor package shown in FIG. 15 is described with respect to differences from the semiconductor package described with reference to FIG. 14.

Referring to FIG. 15, the second semiconductor chip 120b may be rotationally symmetrical with the first semiconductor chip 110b. For example, when the second semiconductor chip 120b rotates by 180° in a direction parallel to the vertical direction (e.g., Z direction), the first semiconductor chip 110b and the second semiconductor chip 120b may have a mirror symmetric structure with respect to a reference plane (e.g., XY plane) parallel to the first horizontal direction (e.g., X direction) and the second horizontal direction (e.g., Y direction). The layout 512 of the first power/ground connection structures 115 of the first semiconductor chip 110b may be the same as the layout 512 of the first power/ground connection structures 115 of the first semiconductor chip 110b illustrated in FIG. 14, and the layout 522a of the first power/ground connection structures 115 of the second semiconductor chip 120b may be rotationally symmetrical with the layout 522 of the second power/ground connection structures 125 of the second semiconductor chip 120b illustrated in FIG. 14.

In some embodiments, the second semiconductor chip 120b may be stacked on the first semiconductor chip 110b in an offset stack and may be rotationally symmetrical with the first semiconductor chip 110b simultaneously. An offset distance OD4, which is a distance at which the second semiconductor chip 120b is offset in the first horizontal direction (e.g., X direction) from the edge of the first semiconductor chip 110b may be an odd multiple of the first distance D1. For example, the offset distance OD4 may be one time the first distance D1. In this case, the second input/output connection structures 123H may be electrically connected to the base substrate 210 through the first input/output connection structures 113H or the first input/output dummy structures 113D. In addition, the second power connection structures 125P may be electrically connected to the base substrate 210 through the first power connection structures 115P or the first dummy structures 115D, and the second ground connection structures 125G may be electrically connected to the base substrate 210 through the first ground connection structures 115G or the first dummy structures 115D.

According to some embodiments, a semiconductor package may include a first semiconductor chip and a second semiconductor chip stacked in an offset stack and/or having a rotationally symmetrical structure, the first semiconductor chip and the second semiconductor chip may be connected to a base substrate through different input/output channel lines. Furthermore, the semiconductor package may connect the first semiconductor chip and the second semiconductor chip to different input/output channel lines, and, simultaneously, merge a power signal supply line and a ground signal supply line with respect to the first semiconductor chip and the second semiconductor chip through a layout of power/ground connection structures of the first semiconductor chip and the second semiconductor chip.

While the inventive concept has been particularly shown and described with reference to embodiments thereof, it will be understood that various changes in form and details may be made therein without departing from the spirit and scope of the following claims.

1. A semiconductor package comprising:
a base substrate;
a first semiconductor chip mounted on the base substrate, and comprising a first substrate and first conductive connection structures extending into the first substrate, wherein the first conductive connection structures have a first pitch interval in a first direction and a second pitch interval in a second direction perpendicular to the first direction; and
a second semiconductor chip mounted on the first semiconductor chip in a third direction perpendicular to the first direction and the second direction, and comprising a second substrate and second conductive connection structures extending into the second substrate, wherein the second conductive connection structures have the first pitch interval in the first direction and the second pitch interval in the second direction,
wherein the first conductive connection structures comprise first power connection structures, first ground connection structures, and first dummy structures,
wherein any one of the first ground connection structures or any one of the first dummy structures is between two first power connection structures neighboring in the first direction among the first power connection structures, and
wherein any one of the first ground connection structures or any one of the first dummy structures is between two first power connection structures neighboring in the second direction among the first power connection structures.

2. The semiconductor package of claim 1, wherein the first power connection structures are electrically connected to a first power circuit pattern of the first semiconductor chip,
wherein the first ground connection structures are electrically connected to a first ground circuit pattern of the first semiconductor chip, and
wherein the first dummy structures are electrically isolated from the first power circuit pattern and the first ground circuit pattern.

3. The semiconductor package of claim 1, wherein each of the first power connection structures includes a first power through electrode extending into the first substrate, a first power upper pad connected to an upper portion of the first power through electrode, and a first power lower pad connected to a lower portion of the first power through electrode,
wherein each of the first ground connection structures includes a first ground through electrode extending into the first substrate, a first ground upper pad connected to an upper portion of the first ground through electrode, and a first ground lower pad connected to a lower portion of the first ground through electrode, and
wherein each of the first dummy connection structures includes a first dummy through electrode extending into the first substrate, a first dummy upper pad connected to an upper portion of the first dummy through electrode, and a first dummy lower pad connected to a lower portion of the first dummy through electrode.

4. The semiconductor package of claim 1, wherein the second conductive connection structures include second power connection structures, second ground connection structures, and second dummy structures,
wherein the second power connection structures are aligned with the first power connection structures or the first dummy structures in the third direction, and
wherein the second ground connection structures are aligned with the first ground connection structures or the first dummy structures in the third direction.

5. The semiconductor package of claim 4, wherein any one of the second ground connection structures or any one of the second dummy structures is between two second power connection structures neighboring in the first direction among the second power connection structures, and
wherein any one of the second ground connection structures or any one of the second dummy structures is between two second power connection structures neighboring in the second direction among the second power connection structures.

6. The semiconductor package of claim 4, wherein more than half of the second power connection structures are electrically connected to the base substrate through the first power connection structures or the first dummy structures, and
wherein more than half of the second ground connection structures are electrically connected to the base substrate through the first ground connection structures or the first dummy structures.

7. The semiconductor package of claim 4, wherein a layout of the second conductive connection structures is identical to a layout of the first conductive connection structures.

8. The semiconductor package of claim 7, wherein a length of the first semiconductor chip in the first direction is equal to a length of the second semiconductor chip in the first direction,
wherein a length of the first semiconductor chip in the second direction is equal to a length of the second semiconductor chip in the second direction,
wherein the second semiconductor chip protrudes from an edge of the first semiconductor chip by a first offset distance in the first direction, and
wherein the first offset distance is twice the first pitch interval.

9. The semiconductor package of claim 4, wherein a layout of the second conductive connection structures is rotationally symmetrical with a layout of the first conductive connection structures.

10. The semiconductor package of claim 9, wherein a length of the first semiconductor chip in the first direction is equal to a length of the second semiconductor chip in the first direction,
wherein a length of the first semiconductor chip in the second direction is equal to a length of the second semiconductor chip in the second direction,
wherein the second semiconductor chip protrudes from an edge of the first semiconductor chip by a first offset distance in the first direction, and
wherein the first offset distance is equal to the first pitch interval.

11. The semiconductor package of claim 1, wherein, in a layout of the first conductive connection structures, respective ones of the first conductive connection structures arranged in a diagonal direction crossing the first direction and the second direction are of a same type, combinations of some of the first power connection structures and some of the first dummy structures, or combinations of some of the first ground connection structures and others of the first dummy structures.

12. The semiconductor package of claim 1, further comprising conductive bumps between the first conductive connection structures and the second conductive connection structures.

13. The semiconductor package of claim 1, wherein the first semiconductor chip further includes:
first input/output connection structures extending into the first substrate and electrically connected to a first input/output circuit pattern of the first semiconductor chip; and
first input/output dummy structures extending into the first substrate and electrically isolated from the first input/output circuit pattern, and
wherein the second semiconductor chip further includes:
second input/output connection structures extending into the second substrate and electrically connected to a second input/output circuit pattern of the second semiconductor chip; and
second input/output dummy structures extending into the second substrate and electrically isolated from the second input/output circuit pattern,
wherein the first input/output connection structures are electrically connected to first channel pads of the base substrate, and
wherein the second input/output connection structures are electrically connected to second channel pads of the base substrate through the first input/output dummy structures.

14. The semiconductor package of claim 13, wherein the first input/output connection structures, the first input/output dummy structures, the second input/output connection structures, and the second input/output dummy structures are each arranged in the second direction,
wherein the first input/output dummy structures are spaced apart from the first input/output connection structures in the first direction, and
wherein the second input/output dummy structures are spaced apart from the second input/output connection structures in the first direction.

15. The semiconductor package of claim 14, wherein the first input/output connection structures and the first input/output dummy structures are in a central portion of the first semiconductor chip, and
wherein the first conductive connection structures are on a first edge portion and a second edge portion of the first semiconductor chip spaced apart in the first direction with the central portion of the first semiconductor chip therebetween.

16. A semiconductor package comprising:
a base substrate;
a first semiconductor chip mounted on the base substrate, and comprising a first substrate and first conductive connection structures extending into the first substrate, wherein the first conductive connection structures are arranged in a first direction and a second direction perpendicular to each other; and
a second semiconductor chip mounted on the first semiconductor chip in a third direction perpendicular to the first direction and the second direction, and comprising a second substrate and second conductive connection structures extending into the second substrate, wherein the second conductive connection structures are arranged in the first direction and the second direction,
wherein the first conductive connection structures comprise first power connection structures, first ground connection structures, and first dummy structures,
wherein a structure at a first distance in the first direction from each of the first power connection structures is any one of the first ground connection structures or any one of the first dummy structures,
wherein a structure at a second distance in the second direction from each of the first power connection structures is any one of the first ground connection structures or any one of the first dummy structures,
wherein a structure at the first distance in the first direction from each of the first ground connection structures is any one of the first power connection structures or any one of the first dummy structures,
wherein a structure at the second distance in the second direction from each of the first ground connection structures is any one of the first power connection structures or any one of the first dummy structures, and
wherein the second conductive connection structures comprise:
second power connection structures electrically connected to the base substrate through the first power connection structures or the first dummy structures;
second ground connection structures electrically connected to the base substrate through the first ground connection structures or the first dummy structures; and
second dummy structures.

17. The semiconductor package of claim 16, wherein a length of the first semiconductor chip in the first direction is equal to a length of the second semiconductor chip in the first direction,
wherein a length of the first semiconductor chip in the second direction is equal to a length of the second semiconductor chip in the second direction,
wherein the second semiconductor chip protrudes from an edge of the first semiconductor chip by a first offset distance in the first direction,
wherein the first conductive connection structures have a first pitch interval in the first direction and a second pitch interval in the second direction, and
wherein the second conductive connection structures have the first pitch interval in the first direction and the second pitch interval in the second direction.

18. The semiconductor package of claim 17, wherein a layout of the second conductive connection structures is identical to a layout of the first conductive connection structures, and
wherein the first offset distance is an even multiple of the first distance.

19. The semiconductor package of claim 17, wherein a layout of the second conductive connection structures is rotationally symmetrical with a layout of the first conductive connection structures, and
wherein the first offset distance is an odd multiple of the first distance.

20. (canceled)

21. (canceled)

22. (canceled)

23. A semiconductor package comprising:
a first substrate, first input/output channel structures extending into the first substrate, and first power/ground connection structures extending into the first substrate, wherein the first power/ground connection structures have a first pitch interval in a first direction and a second pitch interval in a second direction perpendicular to the first direction; and
a second semiconductor chip mounted on the first semiconductor chip in a third direction perpendicular to the first direction and the second direction, and comprising a second substrate, second input/output channel structures extending into the second substrate, and second power/ground connection structures extending into the second substrate, wherein the second power/ground connection structures have the first pitch interval in the first direction and the second pitch interval in the second direction,
wherein the first power/ground connection structures comprise:
first power connection structures electrically connected to a first power circuit pattern of the first semiconductor chip;
second ground connection structures electrically connected to a first ground circuit pattern of the first semiconductor chip; and
first dummy structures electrically isolated from the first power circuit pattern and the first ground circuit pattern,
wherein the second power/ground connection structures comprise:
second power connection structures electrically connected to a second power circuit pattern of the second semiconductor chip;
second ground connection structures electrically connected to a second ground circuit pattern of the second semiconductor chip; and
second dummy structures electrically isolated from the second power circuit pattern and the second ground circuit pattern,
wherein any one of the first ground connection structures or any one of the first dummy structures is between two first power connection structures neighboring in the first direction among the first power connection structures,
wherein any one of the first ground connection structures or any one of the first dummy structures is between two first power connection structures neighboring in the second direction among the first power connection structures,
wherein any one of the first power connection structures or any one of the first dummy structures is between two first ground connection structures neighboring in the first direction among the first ground connection structures,
wherein any one of the first power connection structures or any one of the first dummy structures is between two first ground connection structures neighboring in the second direction among the first ground connection structures,
wherein the second power connection structures are aligned with the first power connection structures or the first dummy structures in the third direction,
wherein the second ground connection structures are aligned with the first ground connection structures or the first dummy structures in the third direction,
wherein the first input/output channel structures comprise first input/output connection structures electrically connected to a first input/output circuit pattern and first input/output dummy structures electrically isolated from the first input/output circuit pattern, and
wherein the second input/output channel structures are aligned with the first input/output dummy structures in the third direction.

24. (canceled)

25. (canceled)
